(19) United States
(12) Patent Application Publication
(10) Pub. No.: US 2024/0234763 A1
(43) Pub. Date: Jul. 11, 2024

(54) APPARATUS FOR CONTROLLING FUEL CELL AND CONTROL METHOD THEREOF

(71) Applicant: HYUNDAI MOBIS CO., LTD., Seoul (KR)

(72) Inventors: Joon Ho PARK, Yongin-si (KR); Seul Ki Rom KIM, Yongin-si (KR)

(73) Assignee: HYUNDAI MOBIS CO., LTD., Seoul (KR)

(21) Appl. No.: 18/409,004

(22) Filed: Jan. 10, 2024

(30) Foreign Application Priority Data
Jan. 11, 2023 (KR) 10-2023-0004042

(51) Int. Cl. H01M 8/04664; H01M 8/04537; H01M 8/04858

(52) U.S. Cl. CPC H01M 8/04679; H01M 8/04559; H01M 8/0491; H01M 2220/20

(57) ABSTRACT

A method and apparatus for controlling a fuel cell is provided. The apparatus includes: a monitoring processor connected to a fuel cell and measures a voltage drop of the fuel cell and inter-cell voltages of the fuel cell; and a processor determines a failure of the fuel cell based on a measured cell value of the monitoring processor. The monitoring processor includes: connection terminals connected between the cells of the fuel cell, respectively; switches respectively connected to the connection terminals and configured to switch on or switch off; and current sources each configured to include: one end connected to each of the switches; and a current having a predetermined size flow therein. The processor controls the switch so that a pull-down current flows into the current source; and determine a failure of the fuel cell based on a difference between the inter-cell voltages of the fuel cell.

### CROSS-REFERENCE TO RELATED APPLICATION

This application claims the benefit under 35 U.S.C. § 119 to Korean Patent Application No. 10-2023-0004042, filed on Jan. 11, 2023, which is incorporated by reference for all purposes.

### BACKGROUND

### 1. Field

Exemplary embodiments of the present disclosure relate to an apparatus for controlling a fuel cell and a control method thereof, and to an apparatus for controlling a fuel cell, which monitors the state of a fuel cell and diagnoses a failure of the fuel cell by measuring an inter-cell voltage of the fuel cell and a control method thereof.

### 2. Description of Related Art

A fuel cell is an energy conversion apparatus for directly converting chemical energy of fuel into electrical energy by a chemical reaction, and continues to generate electricity as long as fuel is supplied thereto and does not need to be recharged unlike a common battery.

The fuel cell has a form in which an electrolyte and two electrodes are stacked like a sandwich, and generates electricity and produces heat and water as its byproducts when oxygen (O2) and hydrogen (H2) flow into the two electrodes, respectively.

The fuel cell has a form of a stack voltage cell in which a plurality of cells have been stacked in series, and is used in a hydrogen fuel cell vehicle as a power source.

When abnormality occurs in the stack voltage cell, the hydrogen fuel cell vehicle may be in a driving-impossible state. If the hydrogen fuel cell vehicle continues to drive in the state in which the state of the stack voltage cell is abnormal, there is a problem in that a failure occurs in the stack voltage cell.

The abnormality of the stack voltage cell may occur due to a voltage reduction attributable to a hydrogen shortage phenomenon or a disconnection of a connection line to which the stack voltage cell is connected.

Accordingly, there is a need for means for monitoring the state of a stack voltage cell by measuring a cell voltage of the stack voltage cell in order to check the abnormality of the stack voltage cell.

In particular, a disconnection of a connection line may occur due to a physical factor or an electrical factor. There is a need for a scheme for periodically checking and diagnosing whether the disconnection has occurred because an error may occur in the monitoring of the cell voltage when the disconnection occurs.

However, if it is determined that the disconnection has occurred by measuring the cell voltage, there is a problem in that an error occurs in the measurement of the cell voltage because a difference between currents flowing into pins may occur for each pin even in a voltage drop value attributable to filter resistance because the currents are different from each other.

The Background of the present disclosure was disclosed in Korean Patent Application Publication No. 10-2019-0024278 (Mar. 8, 2019).

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

Various embodiments are directed to providing an apparatus for controlling a fuel cell, which minimizes a measurement error by measuring a cell voltage of a fuel cell in the state in which a static current source has been connected to each of the cells of the fuel cell and the same current flows into the cells of the fuel cell, and monitors the state of the fuel cell and diagnoses a failure of the fuel cell based on the measured cell voltage, and a control method thereof.

In a general aspect of the disclosure, an apparatus for controlling a fuel cell, includes: a monitoring processor connected to a fuel cell and configured to measure a voltage drop of the fuel cell and inter-cell voltages of the fuel cell; and a processor configured to determine a failure of the fuel cell based on a measured cell value of the monitoring processor, wherein the monitoring processor includes: connection terminals connected between the cells of the fuel cell, respectively; switches respectively connected to the connection terminals and configured to switch on or switch off; and current sources each configured to include: one end connected to each of the switches; and a current having a predetermined size flow therein, wherein the processor is further configured to: control the switch so that a pull-down current flows into the current source; and determine a failure of the fuel cell based on a difference between the inter-cell voltages of the fuel cell.

The monitoring processor may be further configured to form a discharge path as the pull-down current having the predetermined size flows into the current source when the switch becomes on.

The current source may include a static current source connected to each of the connection terminals and configured to include a current having a predetermined size flow therein regardless of a cell voltage of the fuel cell.

The processor may be further configured to: calculate a difference between the inter-cell voltages of the fuel cell after controlling the switch to become on; determine the fuel cell to be normal when the difference is equal to or greater than a set value; and determine the fuel cell to have a disconnection failure when the difference is less than the set value.

The monitoring processor may include: a first multiplexer (MUX) connected to the connection terminal and configured to select and output any one of signals output by the connection terminals; a second MUX; a first level shifter configured to convert a level of an output value of the first MUX; a second level shifter configured to convert a level of an output value of the second MUX; a first analog-to-digital converter (ADC) configured to convert an output value of the first level shifter into a digital signal; and a second ADC configured to convert an output value of the second level shifter into a digital signal, wherein the processor may be further configured to detect a failure of the monitoring processor by comparing a first voltage value that is output through the first MUX, the first level shifter, and the first ADC and a second voltage value that is output through the second MUX, the second level shifter, and the second ADC.
6. The processor may be further configured to: determine the monitoring processor to be normal when the first voltage value and the second voltage value are identical with each other or a difference between the first voltage value and the second voltage value is equal to or smaller than an error range, and determine the monitoring processor to have a failure when the difference between the first voltage value and the second voltage value is greater than the error range.

The first MUX and the second MUX may be connected between the connection terminals so that the first MUX and the second MUX cross each other, and are connected to any one of the plurality of cells of the fuel cell.

In another general aspect of the disclosure, a control method of an apparatus for controlling a fuel cell, includes: connecting cells of a fuel cell to connection terminals of a monitoring processor and respectively controlling, by a processor, switches connected to the connection terminals; controlling a pull-down current flow from the fuel cell to a current source connected to each of the switches; measuring, by the monitoring processor, inter-cell voltages of the cells; and determining, by the processor, a failure of the fuel cell based on a difference between the inter-cell voltages of the fuel cell.

In the controlling of the pull-down current flow, the monitoring processor may be configured to form a discharge path as a current having a predetermined size flows from the fuel cell to the current source by the switch.

In the controlling of the pull-down current flow, the current source may be a static current source connected to each of the connection terminals and configured to include a current having an identical current flow therein regardless of a cell voltage of the fuel cell.

In the determining of the failure of the fuel cell, the processor may be configured to: determine the fuel cell to be normal when a difference between the inter-cell voltages of the fuel cell is equal to or greater than a set value; and determine the fuel cell to have a disconnection failure when the difference is less than the set value.

The method may further include, after determining the failure of the fuel cell, measuring a first voltage value that is output through a first multiplexer (MUX), a first level shifter, and a first analog-to-digital converter (ADC) that are connected to the connection terminals and a second voltage value that is output through a second MUX, a second level shifter, and a second ADC that are connected to the connection terminals; comparing the first voltage value and the second voltage value; and detecting a failure of the monitoring processor based on a result of the comparison.

In the detecting of the failure of the monitoring processor, the processor may be configured to: determine the monitoring processor to be normal when the first voltage value and the second voltage value are identical with each other or a difference between the first voltage value and the second voltage value is equal to or smaller than an error range; and determine the monitoring processor to have a failure when the difference between the first voltage value and the second voltage value is greater than the error range.

In the detecting of the failure of the monitoring processor, the first MUX and the second MUX may be connected between the connection terminals so that the first MUX and the second MUX cross each other, and may be connected to any one of the plurality of cells of the fuel cell.

A measurement error may be minimized by measuring a cell voltage of the fuel cell in a state in which a static current source has been connected to each of the cells of the fuel cell and an equivalent current flows into the cells of the fuel cell, monitoring the state of the fuel cell, and diagnosing a failure of the fuel cell based on the measured cell voltage.

According to the apparatus for controlling a fuel cell and the control method thereof according to embodiments of the present disclosure, it is possible to easily detect abnormality within a circuit for monitoring as well as a fuel cell.

### BRIEF DESCRIPTION OF THE DRAWINGS

FIG. 1 is a diagram illustrating a construction of an apparatus for controlling a fuel cell according to an embodiment of the present disclosure.

FIG. 2 is a diagram illustrating a construction of a monitoring processor of the apparatus for controlling a fuel cell according to an embodiment of the present disclosure.

FIG. 3 is a diagram to which reference is made to describe a method of detecting a disconnection of a fuel cell by the apparatus for controlling a fuel cell according to an embodiment of the present disclosure.

FIG. 4 is a diagram illustrating a construction for monitoring and failure diagnosis, of the apparatus for controlling a fuel cell according to an embodiment of the present disclosure.

FIG. 5 is a diagram illustrating a construction for failure diagnosis, of the apparatus for controlling a fuel cell according to an embodiment of the present disclosure.

FIG. 6 is a flowchart illustrating a control method of the apparatus for controlling a fuel cell according to an embodiment of the present disclosure.

### DETAILED DESCRIPTION

Hereinafter, an apparatus for controlling a fuel cell and a control method thereof according to embodiments of the present disclosure will be described with reference to the accompanying drawings. In this process, the thicknesses of lines or the sizes of components illustrated in the drawings may have been exaggerated for the clarity of a description and for convenience' sake. Furthermore, terms to be described below have been defined by taking into consideration their functions in the present disclosure, and may be changed depending on a user or operator's intention or practice. Accordingly, such terms should be defined based on the overall contents of this specification.

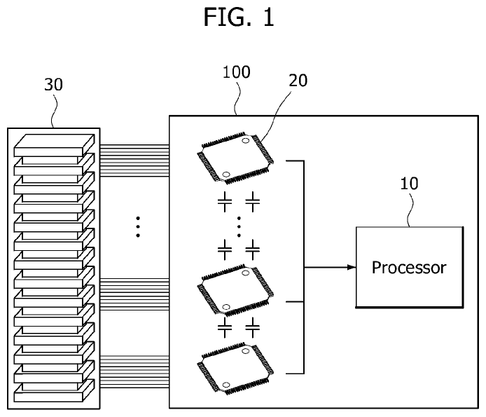

FIG. 1 is a diagram illustrating a construction of an apparatus for controlling a fuel cell according to an embodiment of the present disclosure.

As illustrated in FIG. 1, the apparatus 100 for controlling a fuel cell is connected to a fuel cell 30 consisting of a plurality of cells, and monitors the state of the fuel cell and diagnoses a failure of the fuel cell.

The apparatus 100 for controlling a fuel cell includes a plurality of monitoring processors 20 for measuring a cell voltage of the fuel cell and the state of the fuel cell and a processor 10.

The fuel cell 30 is formed of a stack voltage cell in which a plurality of cells forms a layer and is connected.

The monitoring processors 20 are formed of monitoring semiconductor ICs and connected to the plurality of cells of the fuel cell. The monitoring processors 20 measure a cell voltage of the fuel cell and monitor the state of the fuel cell.

The processor 10 detects the abnormality of the fuel cell based on the cell voltage measured by the monitoring processor 20, and diagnoses a failure of the fuel cell 30. Furthermore, the processor 10 may diagnoses a failure within a circuit of the monitoring processor 20.

The processor 10 may be connected to an electronic control unit (ECU) (not illustrated) of a vehicle in which the fuel cell 30 has been installed, and may transmit data relating to the state and failure of the fuel cell 30.

According to circumstances, the processor 10 may receive data of the monitoring processor 20 through separate insulation communication means (not illustrated) that communicates with the monitoring processor 20.

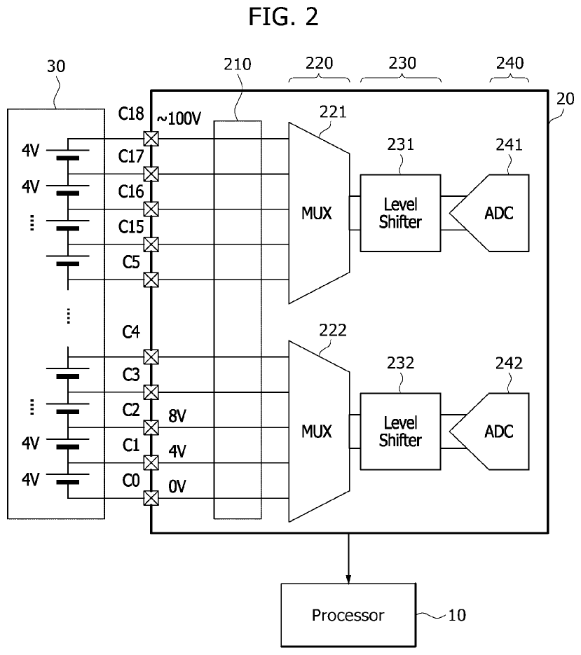

FIG. 2 is a diagram illustrating a construction of the monitoring processor of the apparatus for controlling a fuel cell according to an embodiment of the present disclosure.

As illustrated in FIG. 2, the apparatus 100 for controlling a fuel cell includes the plurality of monitoring processors 20.

Each of the monitoring processors 20 includes a connection terminal C0 to C18, a disconnection detection unit 210, a multiplexer (MUX) 220, a level shifter 230, and an analog-to-digital converter (ADC) 240.

The connection terminal C0 to C18 is provided in a plural number, and is connected to both ends of each cell of the fuel cell 30. For example, a first connection terminal C0 is connected to one end of a first cell, a second connection terminal C1 is connected between the first cell and a second cell, and a third connection terminal C2 is connected between the second cell and a third cell.

Each of the MUX 220, the level shifter 230, and the ADC 240 is provided in a plural number.

The disconnection detection unit 210 is connected between the connection terminal C0 to C18 and the MUX 20, and detects a disconnection of the fuel cell 30 by measuring a cell voltage of the fuel cell 30.

The MUX 220 (221 and 222) is connected to the disconnection detection unit 210 and the connection terminal C0 to C18, and it selects one of a plurality of signals and applies the selected signal to the level shifter 230. The level shifter 230 (231 and 232) changes the level of a signal output by the MUX 220 and applies the signal to the ADC 240. The ADC 240 converts a signal applied thereto into a digital signal, and outputs the digital signal. The converted digital signal is applied to the processor 110.

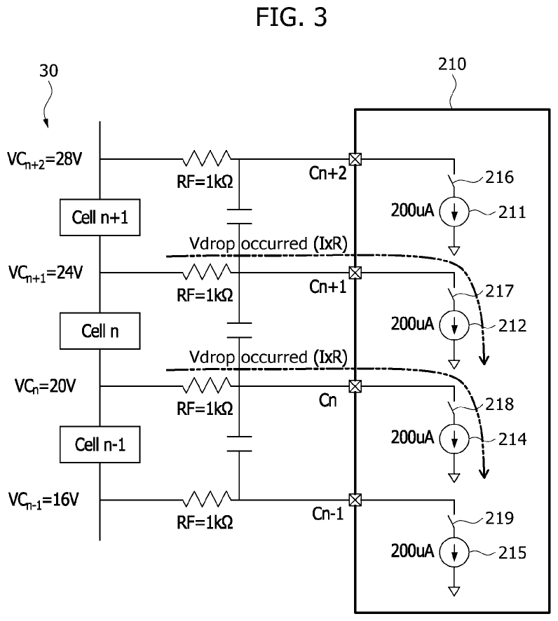

FIG. 3 is a diagram to which reference is made to describe a method of detecting a disconnection of a fuel cell by the apparatus for controlling a fuel cell according to an embodiment of the present disclosure.

As illustrated in FIG. 3, the disconnection detection unit 210 is connected to connection terminals Cn−1, Cn, Cn+1, and Cn+2, and detects a disconnection within the fuel cell 30 by measuring a cell voltage of the fuel cell 30.

Assuming that the cell voltage of the fuel cell 30 is 4 V, a voltage of 20 V (VCₙ) is applied between an (n−1)-th cell Cell n−1 and an n-th cell Cell n and a voltage of 24 V (VCₙ₊₁) is applied between the n-th cell Cell n and an (n+1)-th cell Cell n+1 because the plurality of cells is connected in series.

The disconnection detection unit 210 is connected to the connection terminals Cn−1, Cn, Cn+1, and Cn+2, and includes a plurality of switches 216 to 219 and a plurality of current sources 211 to 214.

The (n−1)-th connection terminal Cn−1 that is connected to one end of the (n−1)-th cell Cell n−1 is connected to a fourth switch 219 and a fourth current source 214. The n-th connection terminal Cn that is connected to one end of the n-th cell Cell n is connected to a third switch 218 and a third current source 213.

The plurality of current sources 211 to 214 is each a static current source into which the same current flows. The size of the current is determined by the size of resistance connected to the current source.

In this case, a voltage drop Vdrop may occur in the n-th cell due to a disconnection of the fuel cell 30.

In the n-th connection terminal Cn, a voltage drop Vdrop of the n-th cell Cell n becomes 200 mV due to resistance RF of 1 kΩ and a current 200 uA. In the (n+1)-th connection terminal Cn+1, a voltage drop Vdrop of the (n+1)-th cell Cell n+1 becomes 200 mV due to resistance RF of 1 kΩ and a current 200 uA. An inter-cell voltage ΔCelln is about 4.0 V, and an error does not occur between the inter-cell voltages.

A case in which a disconnection occurs in the connection of the (n+1)-th cell Cell n+1 is as follows.

When the switches 216 to 219 become off, a pull-down current does not flow into the disconnection detection unit 210. At this time, when a disconnection occurs in the connection of the (n+1)-th cell Cell n+1, the voltage of the (n+1)-th cell Cell n+1 is constantly maintained by a capacitor connected to the connection terminal of the (n+1)-th cell Cell n+1 because a discharge path is not formed from the (n+1)-th cell Cell n+1 to the disconnection detection unit 210.

When the pull-down current does not flow (i.e., the switches OFF), each inter-cell voltage of the fuel cell is maintained to 4 V in a normal situation and a disconnection situation.

When the switches 216 to 219 become on, a pull-down current flows into the disconnection detection unit 210. In the normal situation, the inter-cell voltage of the fuel cell is maintained to 4 V. In the disconnection situation, a difference between the voltage VCₙ₊₁ and the voltage VC becomes a value smaller than 4 V because the voltage VCₙ₊₁ of the (n+1)-th cell is discharged by the current source.

Accordingly, the processor 110 determines that a disconnection has occurred in each cell when a difference between the inter-cell voltages of the fuel cell is less than 4 V in the state in which a pull-down current flows into the disconnection detection unit 210 and a discharge path has been formed from each cell to the disconnection detection unit 210.

In contrast, if resistance is connected, the voltage drop Vdrop of the n-th connection terminal Cn becomes 200 mV due to the resistance RF of 1 kΩ and the current 200 uA because the current 200 uA flows by the voltage 20 V in the n-th connection terminal Cn.

Furthermore, the voltage drop Vdrop of the (n+1)-th connection terminal Cn+1 becomes 240 mV due to the resistance RF of 1 kΩ and the current 240 uA because the current 240 uA flows by the voltage 24 V.

Accordingly, if resistance is used, an error of a voltage drop of 40 mV occurs between the connection terminals. A measurement error occurs because the inter-cell voltage ΔCell n of the n-th cell Cell n becomes about 3.96 V.

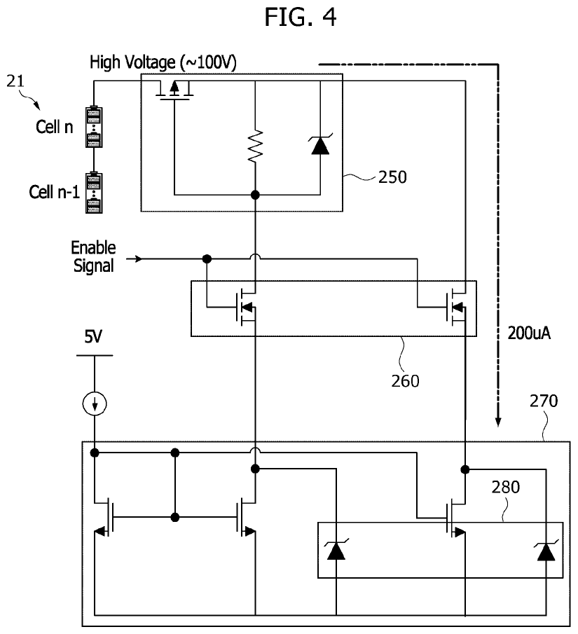

FIG. 4 is a diagram illustrating a construction for monitoring and failure diagnosis, of the apparatus for controlling a fuel cell according to an embodiment of the present disclosure.

As illustrated in FIG. 4, the fuel cell 30 in which the plurality of cells has been connected in series outputs a high voltage of about 100 V. Accordingly, there is a problem in that an element within a semiconductor is damage by a fire if the fuel cell consists of a common current generation circuit because the voltages of the cells correspond to a high voltage having several tens of V.

Accordingly, the apparatus 100 for controlling a fuel cell according to an embodiment of the present disclosure is constructed to be not damaged by a fire even in such a high voltage.

The monitoring processor 20 of the apparatus 100 for controlling a fuel cell further includes a high voltage protection circuit 250 for protecting a circuit against a high voltage applied through a connection terminal thereof, a level shift circuit 260, and a current generation circuit 270 including a diode 280 for protection.

The level shift circuit 260 shifts the level of a high voltage, allows a diagnosis current to stably flow, and prevents a semiconductor chip (IC) from being damaged by a fire due to a high voltage.

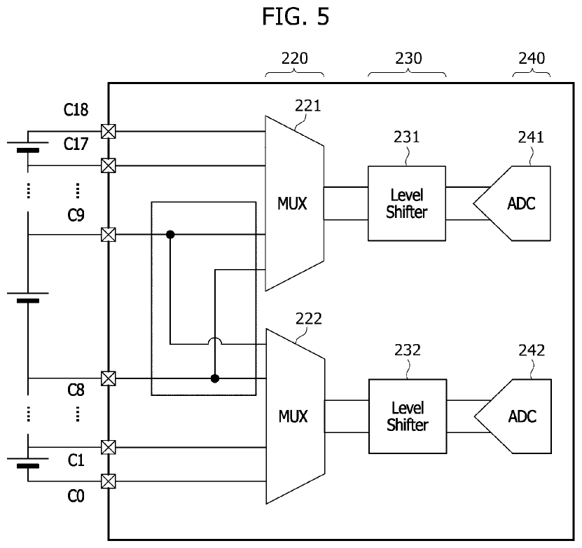

FIG. 5 is a diagram illustrating a construction for failure diagnosis, of the apparatus for controlling a fuel cell according to an embodiment of the present disclosure.

As illustrated in FIG. 5, the apparatus 100 for controlling a fuel cell performs self-diagnosis on the monitoring processor 20.

There is a good possibility that the multiplexer (MUX) 220 (221 and 222) may be damaged by a fire due to the input of a high voltage to a stack cell of the fuel cell 30.

Accordingly, the processor 110 diagnoses a failure of the fuel cell 30 by periodically checking whether the MUX 220 has been damaged by a fire.

The processor 110 checks the abnormality of a circuit of the monitoring processor 20 based on a built-in self-test (BIST).

The processor 110 determines whether a failure has occurred in the monitoring processor 10 by applying the same voltage of cells of the fuel cell 30 to upper and lower MUXes of the MUX 220, that is, a first MUX 221 and a second MUX 222 and comparing voltage values output through ADCs 241 and 242 of the ADC 240, respectively.

The processor 110 determines whether a failure has occurred in the monitoring processor 20 by comparing a first voltage value that is output through the first MUX 221, a first level shifter 231, and a first ADC 241 and a second voltage value that is output through the second MUX 222, a second level shifter 232, and a second ADC 242.

In this case, the processor 110 adds a connection line that is connected to a corresponding connection terminal and a connection between the first MUX 221 and the second MUX 222 and in a way that the connection line intersects the connection terminal and the connection between the first MUX 221 and the second MUX 222 so that the voltage of the n-th cell Cell n of the fuel cell 30 is applied to the first MUX 221 and the second MUX 222, and determines whether voltage values that are output by the first MUX 221 and the second MUX 222 and that are returned by the first ADC 241 and the second ADC 242, respectively, are identical with each other.

The processor 110 compares the first voltage value and the second voltage value that are output through the first ADC 241 and the second ADC 242, after passing through the first MUX 221 and the second MUX 222, respectively.

When the first and second voltage values output through the first ADC 241 and the second ADC 242 are identical with each other, the processor 110 determines that the monitoring processor 20 is normal. Furthermore, when the first and second voltage values output through the first ADC 241 and the second ADC 242 are not identical with each other, but a difference between the first and second voltage values is included within an error range, the processor 110 determines that the monitoring processor 20 is normal.

If the difference between the first and second voltage values deviates from the error range, the processor 110 determines that the monitoring processor 20 has a failure. The processor 110 may determine that any one of the MUX 220 and the ADC 240 has a failure.

The processor 110 may output information on whether the monitoring processor 20 is abnormal through a separate output unit (not illustrated).

Furthermore, the processor 110 may transmit corresponding data to a controller of a vehicle.

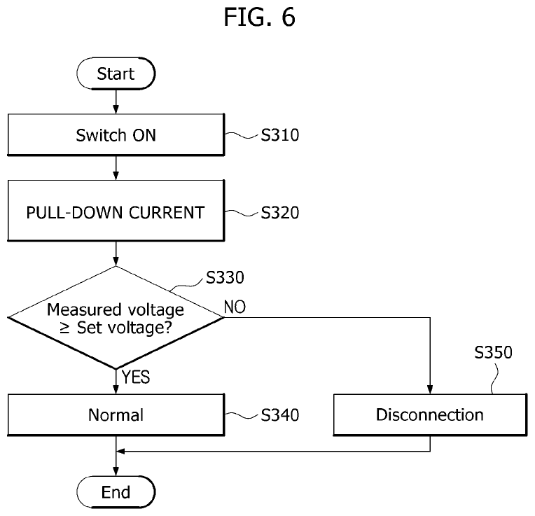

FIG. 6 is a flowchart illustrating a control method of the apparatus for controlling a fuel cell according to an embodiment of the present disclosure.

As illustrated in FIG. 6, the processor 110 detects the state of the fuel cell 30 through the monitoring processor 20. Furthermore, the processor 110 detects the abnormality of a circuit of the monitoring processor 20.

The processor 110 controls the switches 216 to 219 of the disconnection detection unit 210 to become on (S310). Accordingly, a pull-down current flows into the disconnection detection unit 210 (S320).

A current of about 200 uA flows into the current sources 211 to 214. Assuming that a cell voltage is 4 V, the drop of a voltage between the cells becomes 200 mV on the basis of 1 kΩ because the same current flows into the current sources 211 to 214.

When the switches become off, a difference between the inter-cell voltages of the fuel cell is measured to be 4 V in the normal situation. In the case of a disconnection, a difference between the inter-cell voltages of the fuel cell is measured to be 4 V because a separate generation path is not present in the disconnection detection unit 210 and the voltage of each cell is maintained by a corresponding capacitor.

When the switches become on, in the normal situation, a difference between the inter-cell voltages of the fuel cell is identically measured to be 4 V. In the case of a disconnection, a difference between the cell voltage VCₙ₊₁ and the cell voltage VCₙ is measured to be lower than 4 V because the cell voltage VCₙ₊₁ is discharged by using the current source 212 as a discharge path.

Accordingly, the processor 110 determines whether a disconnection occurs by comparing a measured cell voltage and a set voltage based on the inter-cell voltages, which are measured in the state in which the switches become on and a pull-down current flows into the current source (S330).

The processor 110 determines the fuel cell to be normal (S340) when the measured cell voltage is equal to or greater than the set voltage, and determines the fuel cell to have a disconnection when the measured cell voltage is less than the set voltage (S340).

Furthermore, the processor 110 may connect signals that are applied to the multiplexer 220 of the monitoring processor 20 so that the signals cross each other, may process the voltage of a specific cell, for example, the n-th cell Cn, and may compare voltage values that are output through the ADC 240.

The processor 110 may monitor the state of the fuel cell 30 based on the size of a voltage and a converted value, and may detect a disconnection or a failure of a circuit. The processor 110 determines the state of the fuel cell 30 and diagnoses a failure of the fuel cell 30 by receiving voltage values that are output by the plurality of ADCs 241 and 242.

Accordingly, the apparatus for controlling a fuel cell and the control method thereof according to aspects of the present disclosure can improve the accuracy of a determination of a cell voltage and the accuracy of the detection of a failure by reducing an error based on measured inter-cell voltages of the fuel cell in a way that a pull-down current is made to flow by using the current sources. Furthermore, embodiments of the present disclosure can prevent the occurrence of an accident by monitoring the state of a fuel cell and previously detecting the abnormality of the fuel cell.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. An apparatus for controlling a fuel cell, comprising:
a monitoring processor connected to a fuel cell and configured to measure a voltage drop of the fuel cell and inter-cell voltages of the fuel cell; and
a processor configured to determine a failure of the fuel cell based on a measured cell value of the monitoring processor,
wherein the monitoring processor comprises:
connection terminals connected between the cells of the fuel cell, respectively;
switches respectively connected to the connection terminals and configured to switch on or switch off; and
current sources each configured to include:
one end connected to each of the switches; and
a current having a predetermined size flow therein,
wherein the processor is further configured to:
control the switch so that a pull-down current flows into the current source; and
determine a failure of the fuel cell based on a difference between the inter-cell voltages of the fuel cell.

2. The apparatus of claim 1, wherein the monitoring processor is further configured to form a discharge path as the pull-down current having the predetermined size flows into the current source when the switch becomes on.

3. The apparatus of claim 1, wherein the current source comprises a static current source connected to each of the connection terminals and configured to include a current having a predetermined size flow therein regardless of a cell voltage of the fuel cell.

4. The apparatus of claim 1, wherein the processor is further configured to:
calculate a difference between the inter-cell voltages of the fuel cell after controlling the switch to become on;
determine the fuel cell to be normal when the difference is equal to or greater than a set value; and
determine the fuel cell to have a disconnection failure when the difference is less than the set value.

5. The apparatus of claim 1, wherein the monitoring processor comprises:
a first multiplexer (MUX) connected to the connection terminal and configured to select and output any one of signals output by the connection terminals;
a second MUX;
a first level shifter configured to convert a level of an output value of the first MUX;
a second level shifter configured to convert a level of an output value of the second MUX;
a first analog-to-digital converter (ADC) configured to convert an output value of the first level shifter into a digital signal; and
a second ADC configured to convert an output value of the second level shifter into a digital signal,
wherein the processor is further configured to detect a failure of the monitoring processor by comparing a first voltage value that is output through the first MUX, the first level shifter, and the first ADC and a second voltage value that is output through the second MUX, the second level shifter, and the second ADC.

6. The apparatus of claim 5, wherein the processor is further configured to:
determine the monitoring processor to be normal when the first voltage value and the second voltage value are identical with each other or a difference between the first voltage value and the second voltage value is equal to or smaller than an error range, and
determine the monitoring processor to have a failure when the difference between the first voltage value and the second voltage value is greater than the error range.

7. The apparatus of claim 5, wherein the first MUX and the second MUX are connected between the connection terminals so that the first MUX and the second MUX cross each other, and are connected to any one of the plurality of cells of the fuel cell.

8. A control method of an apparatus for controlling a fuel cell, the control method comprising:
connecting cells of a fuel cell to connection terminals of a monitoring processor and respectively controlling, by a processor, switches connected to the connection terminals;
controlling a pull-down current flow from the fuel cell to a current source connected to each of the switches;
measuring, by the monitoring processor, inter-cell voltages of the cells; and
determining, by the processor, a failure of the fuel cell based on a difference between the inter-cell voltages of the fuel cell.

9. The control method of claim 8, wherein in the controlling of the pull-down current flow, the monitoring processor is configured to form a discharge path as a current having a predetermined size flows from the fuel cell to the current source by the switch.

10. The control method of claim 8, wherein in the controlling of the pull-down current flow, the current source is a static current source connected to each of the connection terminals and configured to include a current having an identical current flow therein regardless of a cell voltage of the fuel cell.

11. The control method of claim 8, wherein in the determining of the failure of the fuel cell, the processor is configured to:
determine the fuel cell to be normal when a difference between the inter-cell voltages of the fuel cell is equal to or greater than a set value; and
determine the fuel cell to have a disconnection failure when the difference is less than the set value.

12. The control method of claim 8, further comprising:
after determining the failure of the fuel cell,
measuring a first voltage value that is output through a first multiplexer (MUX), a first level shifter, and a first analog-to-digital converter (ADC) that are connected to the connection terminals and a second voltage value that is output through a second MUX, a second level shifter, and a second ADC that are connected to the connection terminals;
comparing the first voltage value and the second voltage value; and
detecting a failure of the monitoring processor based on a result of the comparison.

13. The control method of claim 12, wherein in the detecting of the failure of the monitoring processor, the processor is configured to:
determine the monitoring processor to be normal when the first voltage value and the second voltage value are identical with each other or a difference between the first voltage value and the second voltage value is equal to or smaller than an error range; and
determine the monitoring processor to have a failure when the difference between the first voltage value and the second voltage value is greater than the error range.

14. The control method of claim 12, wherein in the detecting of the failure of the monitoring processor, the first MUX and the second MUX are connected between the connection terminals so that the first MUX and the second MUX cross each other, and are connected to any one of the plurality of cells of the fuel cell.

15. The control method of claim 8, wherein a measurement error is minimized by measuring a cell voltage of the fuel cell in a state in which a static current source has been connected to each of the cells of the fuel cell and an equivalent current flows into the cells of the fuel cell, monitoring the state of the fuel cell, and diagnosing a failure of the fuel cell based on the measured cell voltage.

16. The apparatus of claim 1, wherein a measurement error is minimized by measuring a cell voltage of the fuel cell in a state in which a static current source has been connected to each of the cells of the fuel cell and an equivalent current flows into the cells of the fuel cell, monitoring the state of the fuel cell, and diagnosing a failure of the fuel cell based on the measured cell voltage.
